(19) United States
(12) Patent Application Publication
(10) Pub. No.: US 2022/0141975 A1
(43) Pub. Date: May 5, 2022

(54) Audiovisual Assembly

(71) Applicant: Tony Malloy, Laurinburg, NC (US)

(72) Inventor: Tony Malloy, Laurinburg, NC (US)

(21) Appl. No.: 17/087,761

(22) Filed: Nov. 3, 2020

(51) Int. Cl. H05K 5/02; H04N 5/225; H04R 3/00; H04R 1/02; G06F 3/041; G06F 3/02; H05K 5/00

(52) U.S. Cl. CPC H05K 5/0217; H04N 5/2252; H04R 3/00; H04R 1/028; G06F 3/041; H04R 2499/15; H05K 5/0017; H05K 5/0086; H05K 5/0234; H04R 2420/07; G06F 3/02

(57) ABSTRACT

An audiovisual assembly for entertainment includes a housing, which define an interior space. A display module and an electronics module are engaged to the housing and positioned in the interior space. The display module comprises a screen, which is selectively extensible from the housing through a slot positioned in a top thereof. A speaker is engaged to the housing. The electronics module is operationally engaged to the display module and the speaker. A remote controller is wirelessly engaged to the electronics module and thus is positioned to selectively signal the electronics module to display content on the screen and to broadcast an audio signal from the speaker.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

The disclosure relates to audiovisual assemblies and more particularly pertains to a new audiovisual assembly for entertainment.

### (2) Description of Related Art Including Information Disclosed Under 37 CFR 1.97 and 1.98

The prior art relates to audiovisual assemblies. Prior art audiovisual assemblies generally comprise rollable projection screens, projection screens having integral speakers, screens that function as a diaphragm for a speaker, screens that extend between pairs of speakers, multidisc compact disc players, flexible displays, and speakers having wheels engaged thereto. What is lacking in the prior art is a portable entertainment assembly having a housing from which a screen is selectively extendible, and where the user can control the screen and audio with a remote controller.

### BRIEF SUMMARY OF THE INVENTION

An embodiment of the disclosure meets the needs presented above by generally comprising a housing, which define an interior space. A display module and an electronics module are engaged to the housing and positioned in the interior space. The display module comprises a screen, which is selectively extensible from the housing through a slot positioned in a top thereof. A speaker is engaged to the housing. The electronics module is operationally engaged to the display module and the speaker. A remote controller is wirelessly engaged to the electronics module and thus is positioned to selectively signal the electronics module to display content on the screen and to broadcast an audio signal from the speaker.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is an isometric perspective view of an audiovisual assembly according to an embodiment of the disclosure.

FIG. 2 is a bottom view of an embodiment of the disclosure.

FIG. 3 is a front view of an embodiment of the disclosure.

FIG. 4 is a side view of an embodiment of the disclosure.

FIG. 5 is a back view of an embodiment of the disclosure.

FIG. 6 is a back view of an alternative embodiment of the disclosure.

### DETAILED DESCRIPTION OF THE INVENTION

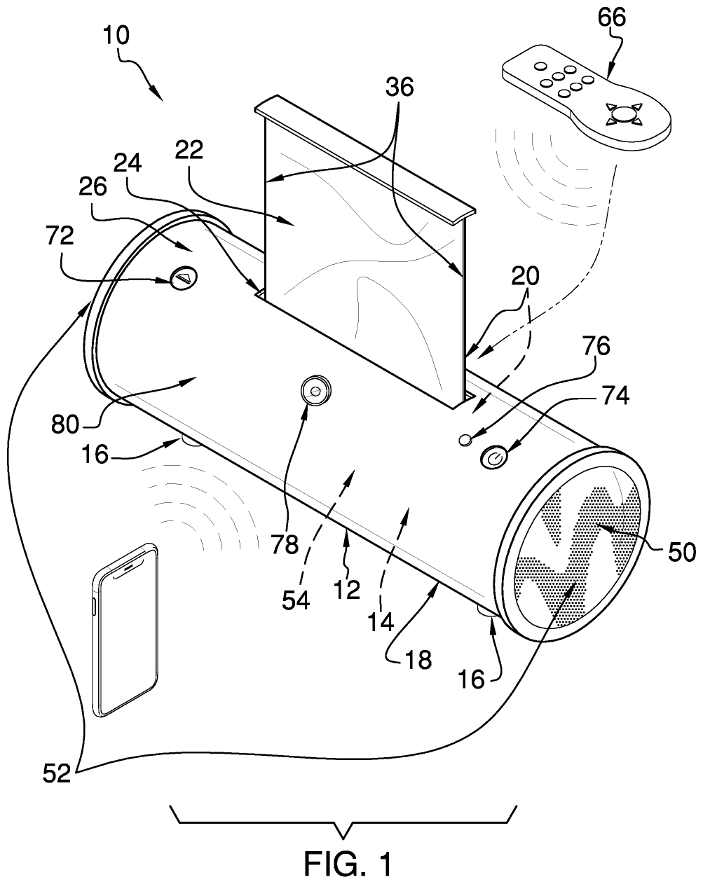

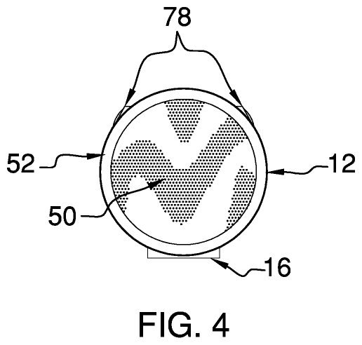

With reference now to the drawings, and in particular to FIGS. 1 through 6 thereof, a new audiovisual assembly embodying the principles and concepts of an embodiment of the disclosure and generally designated by the reference numeral 10 will be described.

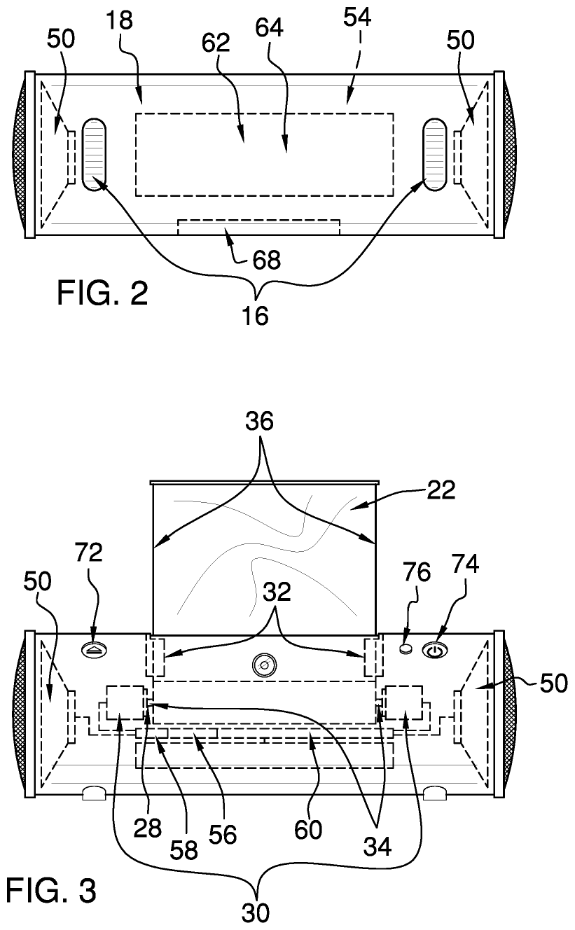

As best illustrated in FIGS. 1 through 6, the audiovisual assembly 10 generally comprises a housing 12, which defines an interior space 14. The housing 12 may be cylindrical, as shown in FIG. 1, although the present invention anticipates the housing 12 being alternatively shaped, such as, but not limited to, rectangularly box shaped, disc shaped, and the like. A set of feet 16 is engaged to a bottom 18 of the housing 12, as shown in FIG. 2. The feet 16 are configured to stabilize the housing 12 on a surface.

A display module 20 is engaged to the housing 12 and is positioned in the interior space 14. The display module 20 comprises a screen 22, which is selectively extensible from the housing 12 through a slot 24 positioned in a top 26 thereof.

The display module 20 may comprise a hub 28, a pair of motors 30, and a pair of tracks 32, as shown in FIG. 3. The screen 22 is rollably positioned around the hub 28. Each motor 30 is axially engaged to a respective opposed end 34 of the hub 28. Each track 32 is slidably engaged to a respective opposed edge 36 of the screen 22 so that the pair of tracks 32 is positioned to guide the screen 22 through the slot 24.

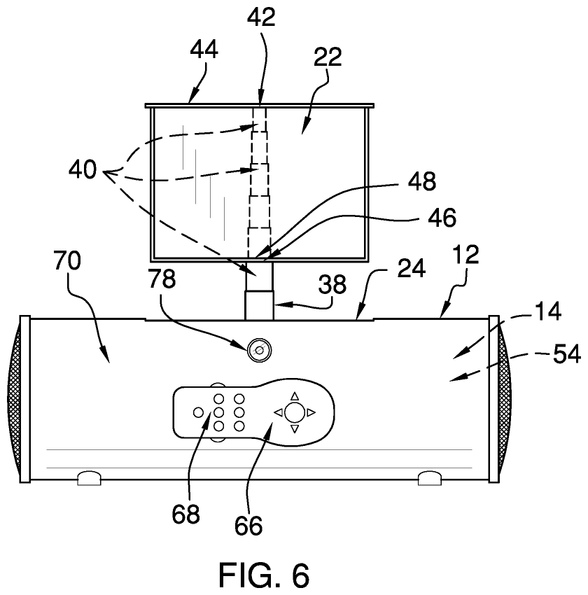

The display module 20 also may comprise a post 38, which is engaged to the housing 12 and which comprises a plurality of nested sections 40, as shown in FIG. 6. The post 38 is selectively extensible through the slot 24. The post 38 has an upper end 42, which is engaged to an upper edge 44 of the screen 22. The screen 22 has a lower edge 46, which is engaged to the post 38 proximate to a midpoint 48 thereof so that the screen 22 is planar when the plurality of nested sections 40 is fully extended.

A speaker 50 is engaged to the housing 12. The speaker 50 may be one of a pair of speakers 50, with each speaker 50 being engaged to a respective opposing end 52 of the housing 12.

An electronics module 54 is engaged to the housing 12 and is positioned in the interior space 14. The electronics module 54 comprises a microprocessor 56 having a transceiver 58 operationally engaged thereto so that the electronics module 54 is equipped for wireless signaling. As such, the electronics module 54 can communicate wirelessly with electronic devices, such as a smart phone, as shown in FIG. 1, allowing audio files, video files, and audiovisual files to be transferred to the electronics module 54. The screen 22 is touch enabled and thus is configured for entry of commands into the microprocessor 56. A data storage module 60 is operationally engaged to the microprocessor 56 so that the electronics module 54 is equipped to selectively store the files, the video files, and the audiovisual files.

A power module 62 is engaged to the housing 12 and is positioned in the interior space 14. The power module 62 is operationally engaged to the electronics module 54 to supply power thereto. The power module 62 comprises a battery 64 so that the housing 12 is portable.

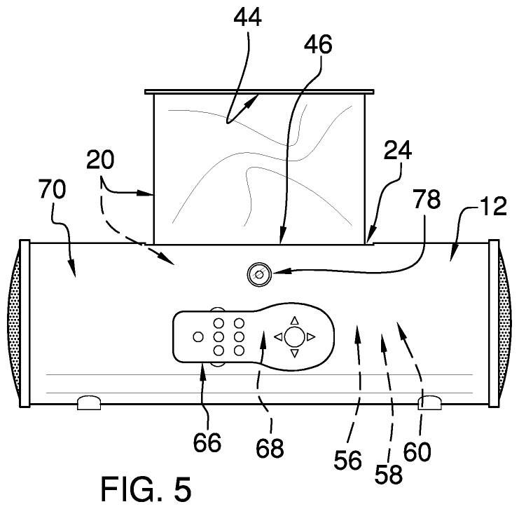

A remote controller 66 is wirelessly engaged to the electronics module 54 and thus is positioned to selectively signal the electronics module 54 to display content on the screen 22 and to broadcast an audio signal from the speaker. The housing 12 has a recess 68 positioned in a back 70 thereof. The remote controller 66 is shaped complementarily to the recess 68 and thus is selectively insertable into the recess 68 to removably engage the remote controller 66 to the housing 12, as shown in FIG. 5.

A button 72, which is depressible, is engaged to the housing 12 and is operationally engaged to the electronics module 54. The button 72 is configured to be depressed to signal the microprocessor 56 to actuate the motor 30 to extend the screen 22 from the slot 24.

A switch 74 is engaged to the housing 12 and is operationally engaged to the microprocessor 56 and the power module 62. The switch 74 is configured to be selectively switched to operationally engage the microprocessor 56 to the power module 62.

A bulb 76 is engaged to the housing 12 and is operationally engaged to the microprocessor 56. The microprocessor 56 is positioned to selectively power the bulb 76 to indicate an operational state of the electronics module 54. The bulb 76 is configured to selectively emit green light when the electronics module 54 is in an operable state and red light when the electronics module 54 is in an inoperable state.

A camera 78 is engaged to the housing 12 and is operationally engaged to the microprocessor 56. The microprocessor 56 is positioned to selectively actuate the camera 78 to capture an image proximate to the housing 12. The camera 78 is one a pair of cameras 78 positioned singly on a front 80 and the back 70 of the housing 12 proximate to the top 26.

In use, the switch 74 is actuated to power up the electronics module 54, which can be paired with a smart phone for transfer of files or streaming content from the smart phone to the electronics module 54. When desired, the button 72 can be pushed to signal the microprocessor 56 to actuate the motors 30 to extend the screen 22 from the housing 12, allowing a user to view a video file. Sound from audio and audiovisual files is broadcast from the speakers 50.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the elements is present, unless the context clearly requires that there be only one of the elements.

I claim:

1. An audiovisual assembly comprising:
a housing defining an interior space;
a display module engaged to the housing and positioned in the interior space, the display module comprising a screen, the screen being selectively extensible from the housing through a slot positioned in a top thereof;
a speaker engaged to the housing;
an electronics module engaged to the housing and positioned in the interior space, the electronics module being operationally engaged to the display module and the speaker; and
a remote controller wirelessly engaged to the electronics module, such that the remote controller is positioned for selectively signaling the electronics module for displaying content on the screen and broadcasting an audio signal from the speaker.

2. The audiovisual assembly of claim 1, wherein the display module comprises:
a hub, the screen being rollably positioned around the hub;
a pair of motors, each motor being axially engaged to a respective opposed end of the hub; and
a pair of tracks engaged to the housing, each track being slidably engaged to a respective opposed edge of the screen, such that the pair of tracks is positioned for guiding the screen through the slot.

3. The audiovisual assembly of claim 1, wherein the display module comprises a post engaged to the housing, the post comprising a plurality of nested sections, such that the post is selectively extensible through the slot, the post having an upper end engaged to an upper edge of the screen, the screen having a lower edge engaged to the post proximate to a midpoint thereof, such that the screen is planar when the plurality of nested sections is fully extended.

4. The audiovisual assembly of claim 1, wherein the speaker is one of a pair of speakers, each speaker being engaged to a respective opposing end of the housing.

5. The audiovisual assembly of claim 1, further including:
the electronics module comprising:
a microprocessor,
a transceiver operationally engaged to the microprocessor, such that the electronics module is equipped for wireless signaling, and
a data storage module operationally engaged to the microprocessor, such that the electronics module is equipped for storing audio files, video files, and audiovisual files; and
a power module engaged to the housing and positioned in the interior space, the power module being operationally engaged to the electronics module for supplying power thereto.

6. The audiovisual assembly of claim 5, wherein the screen is touch enabled, wherein the screen is configured for entry of commands into the microprocessor.

7. The audiovisual assembly of claim 5, wherein the power module comprises a battery, such that the housing is portable.

8. The audiovisual assembly of claim 5, further including a button engaged to the housing and being operationally engaged to the electronics module, the button being depressible, wherein the button is configured for depressing for signaling the microprocessor for actuating the motor for extending the screen from the slot.

9. The audiovisual assembly of claim 5, further including a switch engaged to the housing and being operationally engaged to the microprocessor and the power module, wherein the switch is configured for being selectively switched for operationally engaging the microprocessor to the power module.

10. The audiovisual assembly of claim 9, further including a bulb engaged to the housing and being operationally engaged to the microprocessor, such that the microprocessor is positioned for selectively powering the bulb for indicating an operational state of the electronics module.

11. The audiovisual assembly of claim 10, wherein the bulb is configured for selectively emitting green light when the electronics module is in an operable state and red light when the electronics module is in an inoperable state.

12. The audiovisual assembly of claim 5, further including a camera engaged to the housing and being operationally engaged to the microprocessor, such that the microprocessor is positioned for selectively actuating the camera for capturing an image proximate to the housing.

13. The audiovisual assembly of claim 12, wherein the camera is one a pair of cameras positioned singly on a front and a back of the housing proximate to the top.

14. The audiovisual assembly of claim 1, wherein the housing is cylindrical.

15. The audiovisual assembly of claim 1, wherein:
the housing has a recess positioned in a back thereof; and
the remote controller is shaped complementarily to the recess, such that the remote controller is selectively insertable into the recess for removably engaging the remote controller to the housing.

16. The audiovisual assembly of claim 1, further including a set of feet engaged to a bottom of the housing, wherein the feet are configured for stabilizing the housing on a surface.

17. An audiovisual assembly comprising:
a housing defining an interior space, the housing being cylindrical, the housing having a recess positioned in a back thereof;
a set of feet engaged to a bottom of the housing, wherein the feet are configured for stabilizing the housing on a surface;
a display module engaged to the housing and positioned in the interior space, the display module comprising a screen, the screen being selectively extensible from the housing through a slot positioned in a top thereof, the display module comprising:
a hub, the screen being rollably positioned around the hub,
a pair of motors, each motor being axially engaged to a respective opposed end of the hub, and
a pair of tracks engaged to the housing, each track being slidably engaged to a respective opposed edge of the screen, such that the pair of tracks is positioned for guiding the screen through the slot, or;
a post engaged to the housing, the post comprising a plurality of nested sections, such that the post is selectively extensible through the slot, the post having an upper end engaged to an upper edge of the screen, the screen having a lower edge engaged to the post proximate to a midpoint thereof, such that the screen is planar when the plurality of nested sections is fully extended;
a speaker engaged to the housing, the speaker being one of a pair of speakers, each speaker being engaged to a respective opposing end of the housing;
an electronics module engaged to the housing and positioned in the interior space, the electronics module being operationally engaged to the display module and the speaker, the electronics module comprising:
a microprocessor, the screen being touch enabled, wherein the screen is configured for entry of commands into the microprocessor,
a transceiver operationally engaged to the microprocessor, such that the electronics module is equipped for wireless signaling, and
a data storage module operationally engaged to the microprocessor, such that the electronics module is equipped for storing audio files, video files, and audiovisual files;
a power module engaged to the housing and positioned in the interior space, the power module being operationally engaged to the electronics module for supplying power thereto, the power module comprising a battery, such that the housing is portable;
a switch engaged to the housing and being operationally engaged to the microprocessor and the power module, wherein the switch is configured for being selectively switched for operationally engaging the microprocessor to the power module;
a button engaged to the housing and being operationally engaged to the electronics module, the button being depressible, wherein the button is configured for depressing for signaling the microprocessor for actuating the motor for extending the screen from the slot;
a bulb engaged to the housing and being operationally engaged to the microprocessor, such that the microprocessor is positioned for selectively powering the bulb for indicating an operational state of the electronics module, the bulb being configured for selectively emitting green light when the electronics module is in an operable state and red light when the electronics module is in an inoperable state;
a camera engaged to the housing and being operationally engaged to the microprocessor, such that the microprocessor is positioned for selectively actuating the camera for capturing an image proximate to the housing, the camera being one of a pair of cameras positioned singly on a front and the back of the housing proximate to the top; and
a remote controller wirelessly engaged to the electronics module, such that the remote controller is positioned for selectively signaling the electronics module for displaying content on the screen and broadcasting an audio signal from the speaker, the remote controller being shaped complementarily to the recess, such that the remote controller is selectively insertable into the recess for removably engaging the remote controller to the housing.
